(19) United States
(12) Patent Application Publication
(10) Pub. No.: US 2024/0332208 A1
(43) Pub. Date: Oct. 3, 2024

(54) PRINTED CIRCUIT BOARD

(71) Applicant: SAMSUNG ELECTRO-MECHANICS CO., LTD., Suwon-si (KR)

(72) Inventors: Chi Hyeon JEONG, Suwon-si (KR); Hyun Sang KWAK, Suwon-si (KR); Seong Hwan LEE, Suwon-si (KR)

(73) Assignee: SAMSUNG ELECTRO-MECHANICS CO., LTD., Suwon-si (KR)

(21) Appl. No.: 18/226,994

(22) Filed: Jul. 27, 2023

(30) Foreign Application Priority Data
Mar. 30, 2023 (KR) 10-2023-0041768

(51) Int. Cl. H01L 23/552; H01L 23/13; H01L 23/498; H01L 23/538

(52) U.S. Cl. CPC H01L 23/552; H01L 23/13; H01L 23/49822; H01L 23/5385; H01L 24/13; H01L 24/16; H01L 25/0655; H01L 2224/13111; H01L 2224/13124; H01L 2224/13139; H01L 2224/13147; H01L 2224/16227; H01L 2924/014

(57) ABSTRACT

A printed circuit board includes a substrate portion including a first insulating layer, a first wiring layer disposed on or within the first insulating layer, and a cavity penetrating through at least a portion of the first insulating layer; a connection structure disposed within the cavity of the substrate portion, and including a second insulating layer, a second wiring layer disposed on or within the second insulating layer, and a metal layer disposed on a lower surface and a side surface of the second insulating layer, wherein the metal layer is disposed on an outermost side of the connection structure.

### CROSS-REFERENCE TO RELATED APPLICATIONS

This application claims benefit of priority to Korean Patent Application No. 10-2023-0041768 filed on Mar. 30, 2023 in the Korean Intellectual Property Office, the disclosure of which is incorporated herein by reference in its entirety.

### TECHNICAL FIELD

The present disclosure relates to a printed circuit board.

### BACKGROUND

A multi-chip package including a memory chip such as high bandwidth memory (HBM), a processor chip such as a central processing unit (CPU), a graphics processing unit (GPU), an application specific integrated circuit (ASIC), a field programmable gate array (FPGA), and the like, is being used for data processing that has increased exponentially due to the recent development of artificial intelligence (AI) technology, or the like. In particular, as the number of CPU and GPU cores in server products rapidly increases, die-split technology that can effectively increase the number of cores is becoming common, and die-to-die interconnection is required. Research is being performed to design a substrate to include a connection structure performing die-to-die interconnection to promote a simplified substrate and package structure, improve reliability of the connection structure, and increase yield.

### SUMMARY

An aspect of the present disclosure is to provide a printed circuit board capable of performing die-to-die interconnection in a printed circuit board for mounting an electronic component, a semiconductor chip, and the like.

Another aspect of the present disclosure is to provide a printed circuit board capable of protecting a connection structure from factors inside and outside the board during die-to-die interconnection.

Another aspect of the present disclosure is to provide a printed circuit board capable of improving reliability.

According to an aspect of the present disclosure, provided is a printed circuit board, the printed circuit board including: a substrate portion including a first insulating layer, a first wiring layer disposed on or within the first insulating layer, and a cavity penetrating through t least a portion of the first insulating layer; a connection structure disposed within the cavity of the substrate portion, and including a second insulating layer, a second wiring layer disposed on or within the second insulating layer, and a metal layer disposed on a lower surface and a side surface of the second insulating layer, wherein the metal layer is disposed on an outermost side of the connection structure.

According to another aspect of the present disclosure, provided is a printed circuit board, the printed circuit board including: a substrate portion including a first insulating layer, a first wiring layer disposed on or within the first insulating layer, and a cavity penetrating through at least a portion of the first insulating layer; and a connection structure disposed within the cavity of the substrate portion, and including a second insulating layer, a second wiring layer disposed on or within the second insulating layer, a protective layer covering a lower surface and a side surface of the second insulating layer, and a metal layer disposed on the protective layer.

### BRIEF DESCRIPTION OF DRAWINGS

The above and other aspects, features, and advantages of the present disclosure will be more clearly understood from the following description, taken detailed in conjunction with the accompanying drawings, in which:

FIG. 1 is a block diagram schematically illustrating an example of an electronic device system;

FIG. 2 is a perspective view schematically illustrating an example of an electronic device;

FIGS. 3 and 4 are cross-sectional views schematically illustrating a printed circuit board according to an example;

FIGS. 5 and 6 are cross-sectional views schematically illustrating a printed circuit board according to another example;

FIGS. 7 and 8 are cross-sectional views schematically illustrating a printed circuit board according to another example;

FIGS. 9A and 9B are cross-sectional views schematically illustrating a connection structure according to various examples; and

FIGS. 10A and 10B are cross-sectional views schematically illustrating a method of manufacturing a connection structure according to various examples.

### DETAILED DESCRIPTION

Hereinafter, embodiments of the present disclosure will be described as follows with reference to the attached drawings. The shapes and sizes of elements in the drawings may be exaggerated or reduced for clearer description.

### Electronic Device

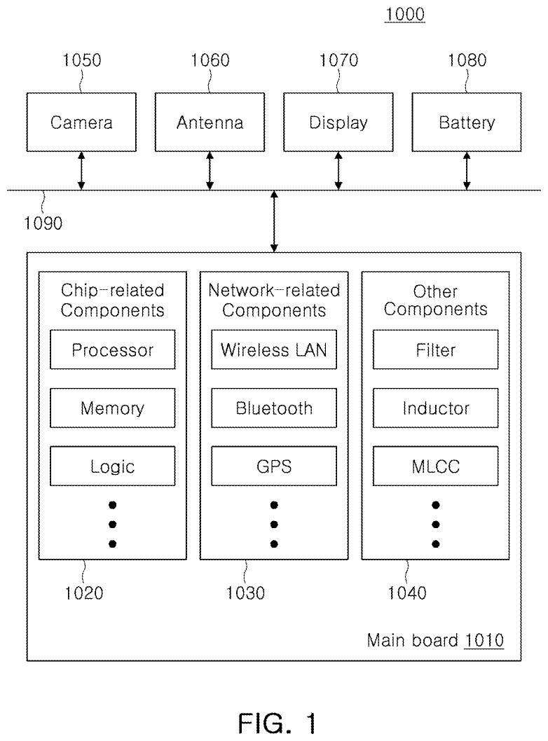

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Also, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. The other components may include, for example, a camera module 1050, an antenna 1060, a display device 1070, and a battery 1080. F the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

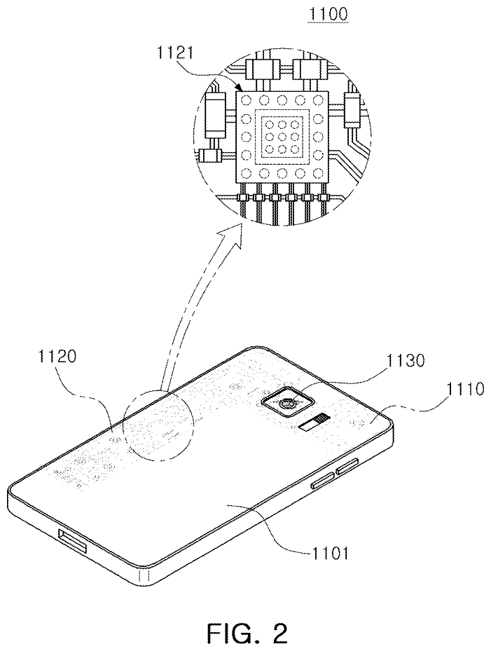

FIG. 2 is a perspective view illustrating an example of an electronic device.

Referring to FIG. 2, the electronic device may be, for example, a smartphone 1100. For example, a motherboard 1110 may be accommodated in the smartphone 1100, and various electronic components 1120 may be physically or electrically connected to the motherboard 1110. Also, other components which may or may not be physically or electrically connected to the motherboard 1110, such as a camera module 1130 and/or a speaker 1140, may be accommodated in the body 1101. A portion of the electronic components 1120 may be the chip related components, a component package 1121, for example, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. The electronic device is not necessarily limited to the smartphone 1100, but may be other electronic devices as described above.

### Printed Circuit Board

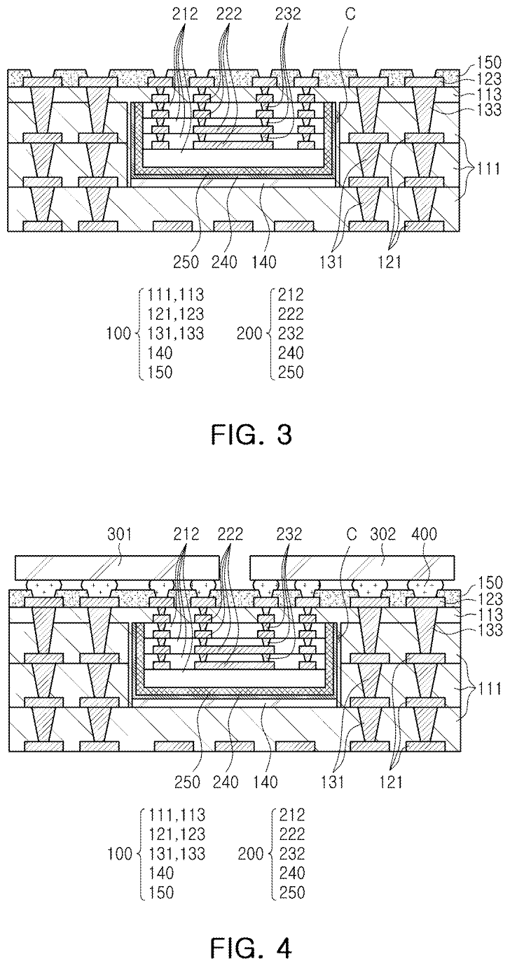

FIGS. 3 and 4 are cross-sectional views illustrating a printed circuit board according to an example.

Referring to FIG. 3, a printed circuit board according to an example includes a substrate portion 100 and a connection structure 200. The substrate portion 100 is a portion implementing a signal path of the printed circuit board, and the connection structure 200 corresponds to a portion connecting components such as chips, or the like to each other. The connection structure 200 is a portion implementing a fine signal path corresponding to electronic components such as fine chips, or the like, and a plurality of electronic components such as a plurality of chips, or the like, may be disposed with the connection structure 200 interposed therebetween, and the connection structure 200 corresponds to a portion maintaining an electrical signal path by performing interconnection of electronic components, such as chips, or the like.

The substrate portion 100 may include a first insulating layer 111, a first wiring layer 121 disposed on or within the first insulating layer 111, and a cavity penetrating through at least portion of the first insulating layer 111. The substrate portion 100 may include a first via layer 131 penetrating through at least a portion of the first insulating layer 111 to connect the first wiring layers 121 to each other.

The first insulating layer 111 may include a plurality of insulating layers, and each first insulating layer 111 may include an insulating material. The insulating material may include a thermosetting resin such as epoxy resin, a thermoplastic resin such as polyimide, or a material including an inorganic filler, an organic filler and/or a glass fiber (glass cloth, and/or glass fabric) together with the above-mentioned resins. The insulating material may be a photosensitive material and/or a non-photosensitive material. For example, as an insulating material of the first insulating layer 111, solder resist (SR), Ajinomoto build-up film (ABF), FR-4, bismaleimide triazine (BT), prepreg (PPG), resin coated copper (RCC) insulating material, copper clad laminate (CCL) may be used, but an example embodiment thereof is not limited thereto, and other polymeric materials may be used.

The first wiring layer 121 may include a plurality of wiring layers, and each first wiring layer 121 may include a metal material. As the metal material, copper (Cu), aluminum (Al), silver (Ag), tin (Sn), gold (Au), nickel (Ni), lead (Pb), titanium (Ti), or alloys thereof may be used. Each of the first wiring layers 121 may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. If necessary, copper foil may be further included. Each of the first wiring layers 121 may perform various functions depending on the design of the corresponding layer. For example, the first wiring layer 121 may include ground patterns, power patterns, signal patterns, and the like. Here, the signal patterns may include various signals, e.g., data signals, other than ground patterns, power patterns, and the like. Each of these patterns may include a line pattern, a plane pattern, and/or a pad pattern.

The first via layer 113 may include a plurality of via layers, and each first via layer 113 may include a micro via. The micro via may be a filled via filling a via hole or a conformal via disposed on a wall surface of the via hole. The micro via may be disposed in a stacked type and/or a staggered type. Each of the first via layers 113 may include a metal material. As the metal material, copper (Cu), aluminum (Al), silver (Ag), tin (Sn), gold (Au), nickel (Ni), lead (Pb), titanium (Ti), or alloys thereof may be included. Each connection via layer may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. The first via layer 113 may perform various functions according to the design of the corresponding layer. For example, the first via layer 113 may include ground vias, power vias, signal vias, and the like. Here, the signal vias may include vias for transferring various signals other than ground vias, power vias, and the like, for example, data signals, or the like.

Each of the first wiring layers 121 and each of the first via layers 113 may be integrally formed with each other, but the present disclosure is not limited thereto. The first wiring layer 121 and the first via layer 113 may be formed by any one of a Semi Additive Process (SAP), Modified Semi Additive Process (MSAP), Tenting (TT), or Subtractive method, but the present disclosure is not limited thereto, and any method capable of configuring a circuit on a printed circuit board can be used without limitations.

Meanwhile, in FIG. 3, the first insulating layer 111 is expressed as being comprised of three layers and has a corresponding number of first wiring layers 121 and first via layers 113, but the present disclosure is not limited thereto. Here, the number of layers of the first insulating layer 111, the first wiring layer 121, and the first via layer 113 may be changed according to design. In particular, the first insulating layer 111 may further include a core insulating layer including a core, the first wiring layer 121 may include copper foil, and the first via layer 113 may also include a through-via penetrating the core insulating layer. As described above, the first insulating layer 111, the first wiring layer 121, and the first via layer 113 of the printed circuit board according to an example may have a configuration that can be used by those skilled in the art of printed circuit boards.

The cavity C may penetrate through at least a portion of the first insulating layer 111. As will be described later, the cavity C may correspond to a position in which the connection structure 200 is mounted. The fact that the cavity C can penetrate through at least a portion of the first insulating layer 111 may mean penetrating through all of any first consecutive insulating layers 111 among the plurality of first insulating layers, mean penetrating only a portion of any first consecutive insulating layers 111 among the plurality of first insulating layers, but the present disclosure is not limited thereto, and may mean penetrating only a portion of any first insulating layer 111 while penetrating through any first consecutive insulating layers. Although not illustrated in FIG. 3, when the cavity C penetrates only a portion of the first insulating layer 111, an upper surface of the first insulating layer 111 may have a step portion.

As a method for forming the cavity C, a method used in a known process for forming a cavity may be used without limitations. For example, a mechanical drilling process such as laser processing or a sandblasting process may be used, but the present disclosure is not limited thereto. In this case, a portion of the first wiring layer 121 disposed on the first insulating layer 111 may function as a stopper layer, and a separate stopper layer may be previously disposed on an upper surface of the first insulating layer 111 and then may be removed by etching after processing the cavity C. When a separate stopper layer is disposed on the upper surface of the first insulating layer 111, the stopper layer may be formed simultaneously with the first wiring layer 121. A wall surface of the cavity C penetrating through at least a portion of the first insulating layer 111 may be comprised of a side surface of the first insulating layer 111, and a bottom surface of the cavity C may be formed of an upper surface of the first insulating layer 111. Meanwhile, although not illustrated in FIG. 3, the bottom surface of the cavity C may be formed of a stopper layer.

A printed circuit board according to an example includes a connection structure 200. The connection structure 200 may be disposed within the cavity C, and the connection structure 200 may include a second insulating layer 212, a second wiring layer 222 disposed on or within the second insulating layer 212, and a metal layer 240 disposed on a lower surface and a side surface of the second insulating layer 212. The connection structure 200 may further include a protective layer 250 disposed between the metal layer 240 and the second insulating layer 212.

The second insulating layer 212 may include a plurality of insulating layers, and each second insulating layer 212 may include an insulating material. The insulating material may include a thermosetting resin such as an epoxy resin, a thermoplastic resin such as a polyimide resin, or a material containing an inorganic filler, an organic filler, and/or a glass fiber together with the thermosetting or thermoplastic resin. The insulating material may be a photosensitive material and/or a non-photosensitive material. For example, the insulating material of the second insulating layer 212, may be an insulating material of prepreg (PPG), resin coated copper (RCC), or the like, but the present disclosure is not limited thereto, and may be an ajinomoto build-up film (ABF), a photoimageable dielectric (PID), FR-4, bismaleimide triazine (BT), and the like. However, the present disclosure is not limited thereto, and if necessary, other polymer materials having excellent rigidity may be used. Meanwhile, the second insulating layer 212 may include an organic insulating material. For example, the connection structure 200 may be an organic bridge. Therefore, even when the connection structure 200 is disposed on an upper side of the substrate 100, unlike the case in which the connection structure 200 is a silicon bridge, a reliability problem due to a coefficient of thermal expansion (CTE) mismatch may hardly occur. In addition, when the connection structure 200 includes an organic insulating material, the difficulty and cost of the formation process may be reduced. A photoimageable dielectric (PID) may be used as an organic insulating material to form a microcircuit, but the present disclosure is not limited thereto.

The second wiring layer 222 may include a plurality of wiring layers, and each second wiring layer 222 may include a metal material. As the metal material, copper (Cu), aluminum (Al), silver (Ag), tin (Sn), gold (Au), nickel (Ni), lead (Pb), titanium (Ti), or alloys thereof can be used. Each of the second wiring layers 222 may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. If necessary, copper foil may be further included. Each of the second wiring layers 222 may perform various functions depending on the design of the corresponding layer. For example, the second wiring layer 222 may include ground patterns, power patterns, signal patterns, and the like. Here, the signal patterns may include various signals, e.g., data signals, other than ground patterns, power patterns, and the like. Each of these patterns may include a line pattern, a plane pattern, and/or a pad pattern. A second wiring layer 222 disposed on an uppermost side of the second wiring layers 222 may have a structure exposed from the second insulating layer 212, and may further include a surface treatment layer on the exposed surface.

The second via layer 232 may include a plurality of via layers, and each second via layer 232 may include a micro via. The micro-via may be a filled via filling a via hole or a conformal via disposed on a wall surface of the via hole. The micro via may be disposed in a stacked type and/or a staggered type. Each of the second via layers 232 may include a metal material. As the metal material, copper (Cu), aluminum (Al), silver (Ag), tin (Sn), gold (Au), nickel (Ni), lead (Pb), titanium (Ti), or alloys thereof may be included. Each of the second via layers 232 may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. The second via layer 232 may perform various functions according to the design of the corresponding layer. For example, the second via layer 232 may include ground vias, power vias, signal vias, and the like. Here, the signal vias may include vias for transferring various signals other than ground vias, power vias, and the like, for example, data signals, or the like.

Each of the second wiring layers 222 and each of the second via layers 232 may be integrally formed with each other, but the present disclosure is not limited thereto. The second wiring layer 222 and the second via layer 232 may be formed by any one of a Semi Additive Process (SAP), a Modified Semi Additive Process (MSAP), Tenting (TT), or a Subtractive method, but the present disclosure is not limited thereto, and any method capable of forming a circuit on a printed circuit board, a connection structure, or the like can be used without limitations.

Meanwhile, the connection structure 200 may have a higher wiring density than the substrate portion 100. A higher wiring density is a relative concept, and for example, an average pitch of wirings included in the second wiring layer 222 may be smaller than an average pitch of wirings included in the first wiring layer 121. The pitch may be measured by imaging a cut cross-section of the printed circuit board 100A with a scanning microscope, and the average pitch may be an average value of pitches between wirings measured at five arbitrary points. In addition, an average interlayer insulation distance between the second wiring layers 222 may be smaller than an average interlayer insulation distance between a plurality of first wiring layers 121. The interlayer insulation distance may also be measured by photographing a cut cross-section of the printed circuit board with a scanning microscope, and the average interlayer insulation distance may be an average value of insulation distances between adjacent wiring layers measured at five arbitrary points. That is, the wiring included in the second wiring layer 222 may be a high-density wiring having a smaller line/space (L/S) than the wiring included in the first wiring layer 121. As a non-limiting example, the wiring included in the second wiring layer 222 may have a line/space of about 2/2 μm, but the present disclosure is not limited thereto. As the wiring of the connection structure 200 has a higher density than the wiring of the substrate 100, it can be effective when interconnecting electronic components such as semiconductor chips. That is, it may be effective for die-to-die interconnection.

To this effect, a thickness of the second insulating layer 212 may be less than a thickness of the first insulating layer 111, and a thickness of the second wiring layer 222 may be less than a thickness of the first wiring layer 121. The thickness of the insulating layer is a concept including an approximate thickness, and may mean a distance vertically crossing upper and lower surfaces of the insulating layer. The fact that the thickness of the second insulating layer 212 may be less than the thickness of the first insulating layer 111 may mean that the thickness of any one of the second insulating layers 212 among the plurality of second insulating layers 212 is less than the thickness of any one of the first insulating layers 212 among the plurality of first insulating layers 111, but the present disclosure is not limited thereto. The thicknesses of the first insulating layer 111 and the second insulating layer 212 may be measured by imaging a cut cross-section of the printed circuit board with a scanning microscope, and may be an average value of the thicknesses of the insulating layers measured at five arbitrary points. This analysis may be equally applied to the thicknesses of the first metal layer 240 and the second metal layer 240.

Meanwhile, although not illustrated in FIG. 3, the connection structure 200 may have an embedded trace substrate (ETS) structure. For example, a second wiring layer 222 disposed on an uppermost side may be buried on an upper side of the second insulating layer 212 such that an upper surface thereof is exposed from an upper surface of the second insulating layer 212 disposed on the uppermost side. When the connection structure 200 is formed in the ETS structure, wiring design may be possible with a finer pitch. In addition, compared to a silicon bridge, the connection structure 200 may be manufactured at a lower cost, and the process thereof may be simpler.

The connection structure 200 of the printed circuit board according to an example may include a metal layer 240 disposed on a lower surface and a side surface of the second insulating layer 212, and include a protective layer 250 disposed between the metal layer 240 and the second insulating layer 212.

The protective layer 250 may be a molding material, but the present is not limited thereto, and may cover a lower surface and a side surface of the second insulating layer 212 to protect the second insulating layer 212, the second wiring layer 222, and the second via layer 232 of the connection structure 200. The protective layer 250 may include an insulating material, and correspond to an epoxy molding compound (EMC), but the present disclosure is not limited thereto, and may also include the same insulating material as the second insulating layer 212. That is, the protective layer 250 can be used without limitations as long as the protective layer 250 is disposed on a lower portion or a side portion of the connection structure 200 and may cover the second insulating layer 212 so as to be in contact with the second insulating layer 212. The protective layer 250 may perform a function of protecting other components of the connection structure 200 from external impact, or the like, and may increase bonding strength with the metal layer 240. Meanwhile, the protective layer 250 may be omitted in some cases.

The metal layer 240 may be disposed on an outermost side of the connection structure 200, and may include a metal material. As the metal material, copper (Cu), aluminum (Al), nickel (Ni), silver (Ag), tin (Sn), gold (Au), nickel (Ni), lead (Pb), titanium (Ti), molybdenum (Mo), stainless metal (SUS), alloys thereof, or the like may be used.

As wiring density of the connection structure 200 is higher than wiring density of the substrate portion 100, the wiring disposed in the connection structure 200 may cause electromagnetic interference (EMI), which may cause a problem that the effect therefrom is great. This may occur inside the connection structure 200, but may also occur in the substrate 100, or may occur in a semiconductor chip or outside thereof. As the metal layer 240 is disposed on an outermost side of the connection structure 200, the connection structure 200 may obtain an effect capable of EMI shielding. That is, after forming the second insulating layer 212, the second wiring layer 222, and the second via layer 232 of the connection structure 200, the metal layer 240 may be disposed along a lower surface and a side surface of the connection structure 200, so that it may have a structure in which the second wiring layer 222 and the second via layer 232 are EMI shielded by the metal layer 240. Since the connection structure 200 corresponds to a region on which semiconductor chips are mounted and corresponds to a configuration for connecting semiconductor chips to each other, a semiconductor chip is not embedded in the connection structure 200, and the metal layer 240 of the connection structure 200 is included in the connection structure 200 of the printed circuit board.

The metal layer 240 may be formed in a form of a thin film, but the present disclosure is not limited thereto and may be formed through plating. When the metal layer 240 is disposed on the protective layer 250 in a form of a thin film, it may be formed by sputtering a metal material on the protective layer 250, but a method of forming the metal layer 240 is limited thereto. In this case, the metal layer 240 may be integrally formed to extend from a lower surface to a side surface of the connection structure 200. In addition, as described above, when the protective layer 250 is omitted, the metal layer 240 may be disposed on the side surface and lower surface of the second insulating layer 212.

As the metal layer 240 may be disposed in a form of a thin film, a thickness of the metal layer 240 may be thinner than that of the protective layer 250. The thickness of the metal layer 240 may be a thickness measured in a direction perpendicular to the lower surface of the connection structure 200 or in a direction perpendicular to the side surface thereof. That is, the thickness of the metal layer 240 on a lowermost side of the connection structure 200 may mean a thickness of the metal layer 240 measured in a direction perpendicular to the lower surface of the connection structure 200, and the thickness of the metal layer 240 on an outermost side of the connection structure 200 may mean a thickness of the metal layer 240 measured in a direction perpendicular to the side surface of the connection structure 200. The thickness of the metal layer 240 may be measured by imaging a cut cross-section of the printed circuit board with a scanning microscope, and may be an average value of thicknesses of the metal layer 240 measured at five random points. The thickness of the protective layer 250 may be measured in the same manner as the thickness of the metal layer 240.

An upper surface of the metal layer 240 may be substantially coplanar with an upper surface of the second insulating layer 212, and may also be substantially coplanar with an upper surface of the protective layer 250. The fact that two surfaces are coplanar is a concept that includes a concept that certain two surfaces form the same surface without a step, that is, form a coplanar surface. Being substantially coplanar is a concept that includes being approximately coplanar, and may include, for example, errors in the manufacturing process. The upper surface of the metal layer 240 means one surface of the metal layer 240 disposed on the upper surface of the connection structure 200, and may be interpreted in the same manner in the case of the protective layer 250.

As will be described later in a manufacturing operation, after attaching the second insulating layer 212 to a carrier substrate CO through an adhesive film AD, a protective layer 250 and a metal layer 240 may be formed, and then the carrier substrate CO and the adhesive film AD may be removed, so that the upper surface of the metal layer 240, the upper surface of the protective layer 250, and the upper surface of the second insulating layer 212 may be substantially coplanar with each other, and the connection structure 200 may have a structure with a flat upper surface.

Meanwhile, in FIG. 3, it is expressed as including one connection structure 200, but the present disclosure is not limited thereto, and may include a plurality of connection structures 200.

The substrate portion 100 of the printed circuit board according to an example may further include an adhesive layer 140, a third insulating layer 113, a third wiring layer 123, a third via layer 133, and a solder resist layer 150.

The connection structure 200 may be disposed within a cavity C of the substrate portion 100, and the connection structure 200 may be attached to a bottom surface of the cavity C through an adhesive layer 140. As the adhesive layer 140, an adhesive film such as a general die attach film (DAF) may be used, but the present disclosure is not limited thereto, and any means capable of attaching other components such as electronic components, connection structures, or the like, to the printed circuit board, such as using a known tape, or the like, may be used without limitations.

As the connection structure 200 may be disposed within the cavity C through the adhesive layer 140, the metal layer 240 included in the connection structure 200 may be spaced apart from a bottom surface and a wall surface of the cavity. That is, the metal layer 240 may be disposed to be spaced apart from the first insulating layer 111 forming the bottom and wall surfaces of the cavity. This is because a metal layer 240 is disposed on an outermost side of the connection structure 200 in a manufacturing operation of the connection structure 200, and may be distinguished from a form of filling the cavity C with other materials.

The third insulating layer 113 may be disposed on the first insulating layer 111, and may fill the cavity C to cover the connection structure 200. The third insulating layer 113 may include an insulating material, and may include the same material as the first insulating layer 111, but the present disclosure is not limited thereto. The insulating material may include a thermosetting resin such as an epoxy resin, a thermoplastic resin such as a polyimide resin, or a material containing an inorganic filler, an organic filler, and/or a glass fiber together with the thermosetting or thermoplastic resin. The insulating material may be a photosensitive material and/or a non-photosensitive material. For example, the insulating material of the third insulating layer 113 may be an insulating material of prepreg (PPG), resin coated copper (RCC), or the like, but the present disclosure is not limited thereto, and may be an ajinomoto build-up film (ABF), a photo imageable dielectric (PID), FR-4, bismaleimide triazine (BT), and the like. However, the present disclosure is not limited thereto, and if necessary, other polymer materials having excellent rigidity may be used. Meanwhile, in FIG. 3, the third insulating layer 113 is represented as one insulating layer, but the present disclosure is not limited thereto, and the third insulating layer 113 may include a plurality of insulating layers.

The third wiring layer 123 may include a metal material. As the metal material, copper (Cu), aluminum (Al), silver (Ag), tin (Sn), gold (Au), nickel (Ni), lead (Pb), titanium (Ti), or alloys thereof may be used. Each of the third wiring layers 123 may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. If necessary, copper foil may be further included. The third wiring layer 123 may be used as a means to be connected to a semiconductor chip later, but the present disclosure is not limited thereto and may perform various functions according to design. For example, the third wiring layer 123 may include ground patterns, power patterns, signal patterns, and the like. Here, the signal patterns may include various signals, e.g., data signals, other than ground patterns, power patterns, and the like. Each of these patterns may include a line pattern, a plane pattern, and/or a pad pattern. A third wiring of the third wiring layer 123 may be designed to have various sizes or pitches as needed. That is, a third wiring disposed above the first wiring layer 121 and a third connection disposed above the second wiring layer 222 may have different sizes or pitches. In this case, the third wiring disposed above the second wiring layer 222 and the third wiring disposed above the first wiring layer 121 may be implemented more finely. Meanwhile, in FIG. 3, the third wiring layer 123 is represented as one wiring layer, but the present disclosure is not limited thereto, and since the third insulating layer 113 may be formed in plural, the third wiring layer 123 may also be comprised of a plurality of wiring layers to correspond thereto.

The third via layer 133 may include a micro via. The micro via may be a filled via filling a via hole or a conformal via disposed on a wall surface of the via hole. The micro via may be disposed in a stacked type and/or a staggered type. Each of the third via layers 133 may include a metal material. As the metal material, copper (Cu), aluminum (Al), silver (Ag), tin (Sn), gold (Au), nickel (Ni), lead (Pb), titanium (Ti), or alloys thereof may be included. Each of the third via layers 133 may include an electroless plating layer (or chemical copper) as a seed layer and an electrolytic plating layer (or electrolytic copper) as a plating layer, but the present disclosure is not limited thereto. A sputtering layer may be formed instead of chemical copper as the electroless plating layer. The third via layer 133 may perform a function of connecting the first wiring layer 121 or the second wiring layer to the third wiring layer, but the present disclosure is not limited thereto, and may perform various functions according to design. For example, the third via layer 133 may include ground vias, power vias, signal vias, and the like. Here, the signal vias may include vias for transferring various signals other than ground vias, power vias, and the like, for example, data signals, or the like. Meanwhile, in FIG. 3, the third via layer 133 is expressed as one via layer, but the present disclosure is not limited thereto, and since the third insulating layer 113 and the third wiring layer may be configured in plural, the third via layer 133 may be comprised of a plurality of via layers to correspond thereto.

The third wiring layer 123 and the third via layer 133 may be integrally formed with each other, but the present disclosure is not limited thereto. The third wiring layer 123 and the third via layer 133 may be formed by any one of a Semi Additive Process (SAP), Modified Semi Additive Process (MSAP), Tenting (TT), a Subtractive method, or the like, but the present disclosure is not limited, and any method capable of forming circuit patterns and vias on a printed circuit board may be used without limitations.

The solder resist layer 150 may be disposed on the third insulating layer 113, and be disposed on an outermost side of the printed circuit board to protect the printed circuit board from the outside. A known solder resist may be used for the solder resist layer 150, and the solder resist layer 150 may include a thermosetting resin and an inorganic filler dispersed in the thermosetting resin, but may not include glass fibers. The insulating resin may be a photosensitive insulating resin, and the filler may be an inorganic filler and/or an organic filler, but the present disclosure is not limited thereto, and other polymer materials may be used if necessary. The solder resist layer 150 may have an opening, and at least a portion of the third wiring layer 123 may be exposed through the opening. The third wiring layer 123 exposed through the opening may be connected to an electronic component such as a semiconductor chip.

Referring to FIG. 4, a printed circuit board according to an example includes a first semiconductor chip 301 disposed on a portion of a substrate portion 100 and a portion of a connection structure 200 and a second semiconductor chip 302 disposed on a portion of the substrate portion 100 and a portion of the connection structure 200, and includes a connection member 400 connecting the first semiconductor chip 301 and the second semiconductor chip 302 to the substrate 100 and the connection structure 200, respectively. The first semiconductor chip 301 may be disposed to be electrically connected to a portion of the substrate portion 100 and a portion of the connection structure 200, and the second semiconductor chip 302 may be electrically connected to a portion of the substrate portion 100 and a portion of the connection structure 200 to be electrically connected to the first semiconductor chip 301 through the connection structure 200.

The first semiconductor chip 301 and the second semiconductor chip 302 may include an integrated circuit (IC) die in which hundreds to millions of devices are integrated into a single chip, respectively. In this case, the integrated circuit may include, for example, an application processor chip (e.g., AP) such as a central processor (e.g., a central processing unit (CPU)), a graphics processor (e.g., a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like, but the present disclosure is not limited thereto. The integrated circuit may also be other types such as a memory chip such as a volatile memory (e.g., DRAM), a non-volatile memory (e.g., ROM), a flash memory, memory chips such as a high bandwidth memory (HBM), or power management IC (PMIC). For example, the first semiconductor chip 301 may include a logic chip such as a GPU, and the second semiconductor chip 302 may include a memory chip such as HBM. Alternatively, the first and second semiconductor chips 302 may also divided logic chips having different cores by being divided by die splitting.

Each of the first semiconductor chip 301 and the second semiconductor chip 302 may be formed based on an active wafer. In this case, as a base material forming each body, silicon (Si), germanium (Ge), gallium arsenide (GaAs), and the like may be used. Various circuits may be formed in the body. A connection pad may be formed in each body, and the connection pad may include a conductive material such as aluminum (Al) or copper (Cu). The first semiconductor chip and the second semiconductor chip 302 may be bare dies, and in this case, metal bumps may be disposed on the connection pad. Alternatively, the first semiconductor chip 301 and the second semiconductor chip 302 may be packaged dies. In this case, a redistribution layer may be additionally formed on the connection pad, and metal bumps may be disposed on the redistribution layer.

The connection member 400 may be formed of a low melting point metal, for example, solder such as tin (Sn)-aluminum (Al)-copper (Cu), but the present disclosure is not limited thereto. The connection member 400 may be formed of a multilayer or a single layer. When formed as a multilayer, the connection member 400 may include a copper pillar and solder, and when formed as a single layer, the connection member 400 may include tin-silver solder or copper, but the present disclosure is not limited thereto. In addition thereto, any means capable of serving as an intermediary so that a semiconductor chip, electronic component, or the like, is electrically connected to the substrate 100 and/or the connection structure 200 may be used without limitations.

Although it is expressed that two semiconductor chips are mounted in FIG. 4, the present disclosure is not limited thereto, and a larger number of semiconductor chips may be mounted, and a larger number of semiconductor chips may be electrically connected by the connection structure 200.

Meanwhile, the printed circuit board according to an example is not limited to the configurations illustrated in FIGS. 3 and 4, and may further include a general configuration of a printed circuit board in addition thereto. That is, a configuration that can be conceived of by those skilled in the art may be further included.

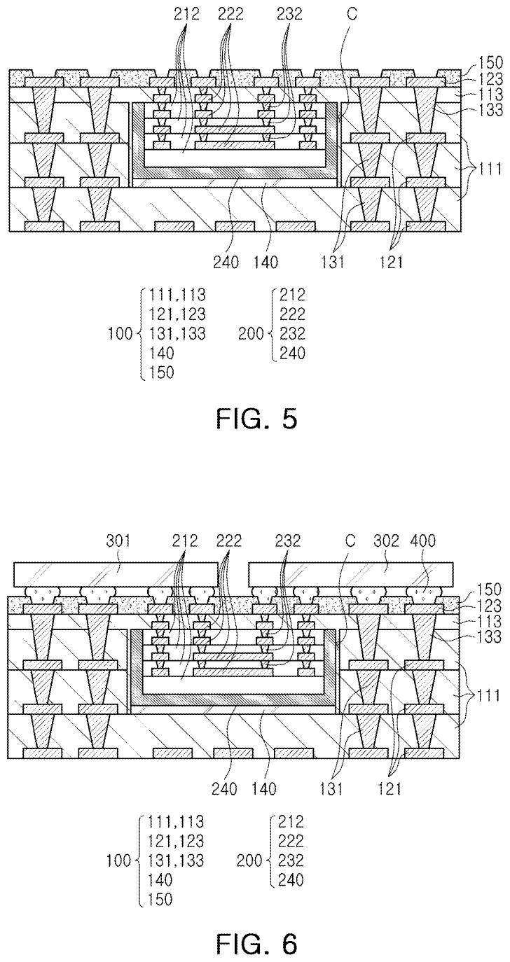

FIGS. 5 and 6 are cross-sectional views schematically illustrating a printed circuit board according to another example.

Referring to FIG. 5, a connection structure 200 of the printed circuit board according to another example may not include a protective layer 250 which is included in the printed circuit board shown in FIG. 3. When the connection structure 200 does not include the protective layer 250, the second insulating layer 212 may be disposed to directly contact a metal layer 240, and the metal layer 240 may cover a second insulating layer 212.

When the protective layer 250 is omitted, the metal layer 240 may be formed through plating. As a method of plating an outermost side of the connection structure 200, any method for edge plating may be used without limitations, but the present disclosure is not limited thereto, and the method of forming the metal layer 240 is not limited, such as a known plating method may be used. When the metal layer 240 is formed through plating, the plating layer 240 may be formed to be thicker than when it is formed in a form of a thin film.

Referring to FIG. 6, a printed circuit board according to another example may further include a first semiconductor chip 301, a second semiconductor chip 302, and a connection member 400. Since descriptions of the first semiconductor chip 301, the second semiconductor chip 302, and the connection member 400 are the same as those of the printed circuit board according to an example, overlapping descriptions thereof will be omitted.

Meanwhile, the same configuration as the printed circuit board according to an example among configurations other than the protective layer 250 and the metal layer 240 may also be applied to the printed circuit board according to another example, and thus, overlapping descriptions thereof will be omitted.

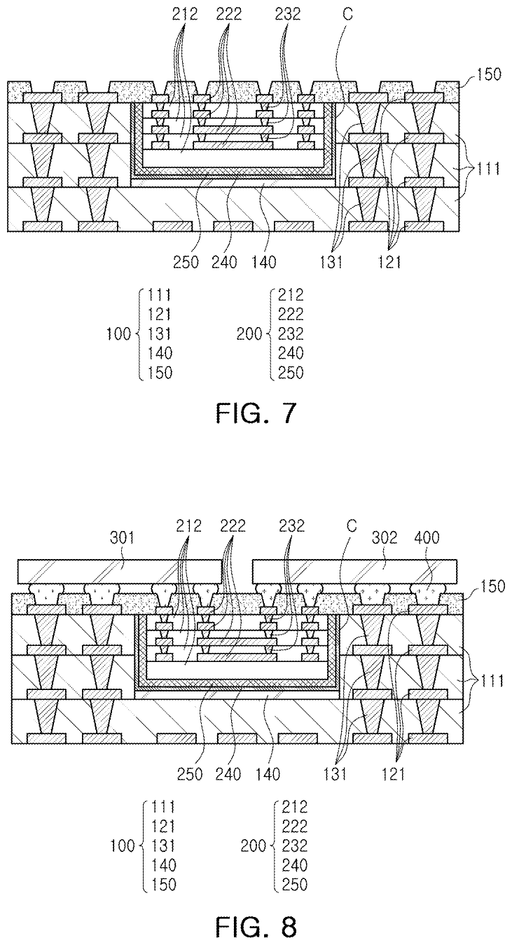

FIGS. 7 and 8 are cross-sectional views schematically illustrating a printed circuit board according to another example.

Referring to FIG. 7, a substrate portion 100 of a printed circuit board according to another example may not include a third insulating layer 113, a third wiring layer 123, and a third via layer 133 that are included in the printed circuit board shown in FIG. 3. That is, after mounting a connection structure 200 within the cavity C, the connection structure 200 may not be buried with the third insulating layer 113.

In FIG. 7, it is illustrated that a width of the cavity C and the width of the connection structure 200 are matched with each other, but the present disclosure is not limited thereto, and the connection structure 200 may be disposed to be spaced apart from a wall surface of the cavity C. In addition, since the third insulating layer 113 is omitted in the substrate portion 100, a solder resist layer 150 may be disposed on the first insulating layer 111. At least a portion of the first wiring layer 121 may be exposed externally through an opening of the solder resist layer 150.

Referring to FIG. 8, a printed circuit board according to another example may further include a first semiconductor chip 301, a second semiconductor chip 302, and a connection member 400. Since descriptions of the first semiconductor chip 301, the second semiconductor chip 302, and the connection member 400 are the same as those of the printed circuit board according to the example, overlapping descriptions thereof will be omitted.

Meanwhile, it is illustrated that the connection structure 200 of the printed circuit board according to another example has the same configuration as the connection structure 200 of the printed circuit board according to an example, but the present disclosure is not limited thereto, and a protective layer 250 may be omitted to have the same configuration as the connection structure 200 of the printed circuit board according to another example. Among the configurations other than the third insulating layer 113, the third wiring layer 123, and the third via layer 133, since the same configuration as the printed circuit board according to an example and the printed circuit board according to another example may also be applied to the printed circuit board according to another example, overlapping descriptions thereof will be omitted.

### Connection Structure and Method of Manufacturing Connection Structure

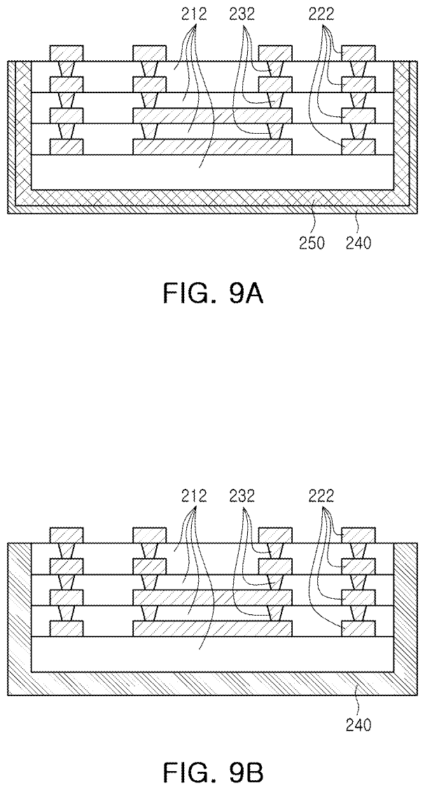

FIGS. 9A and 9B are cross-sectional views schematically illustrating a connection structure according to various examples.

A connection structure 200 illustrated in FIG. 9A is the same as the connection structure 200 included in the printed circuit board according to an example. The connection structure 200 may include a second insulating layer 212, a second wiring layer 222 disposed on or within the second insulating layer 212, a second via layer 232 penetrating through at least a portion of the second insulating layer 212 to the second wiring layer 222 to each other, a metal layer 240 disposed on a lower surface and a side surface of the second insulating layer 212 and disposed on an outermost surface thereof, and a protective layer 250 disposed between the metal layer 240 and the second insulating layer.

A connection structure 200 illustrated in FIG. 9B is the same as the connection structure 200 included in the printed circuit board according to another example. In the connection structure 200 illustrated in FIG. 9B, unlike the connection structure illustrated in FIG. 9A, the protective layer 250 may be omitted.

Since the configuration of the connection structure 200 is the same as the description of the connection structure 200 of the printed circuit board according to an example and the printed circuit board according to another example, duplicate descriptions thereof will be omitted.

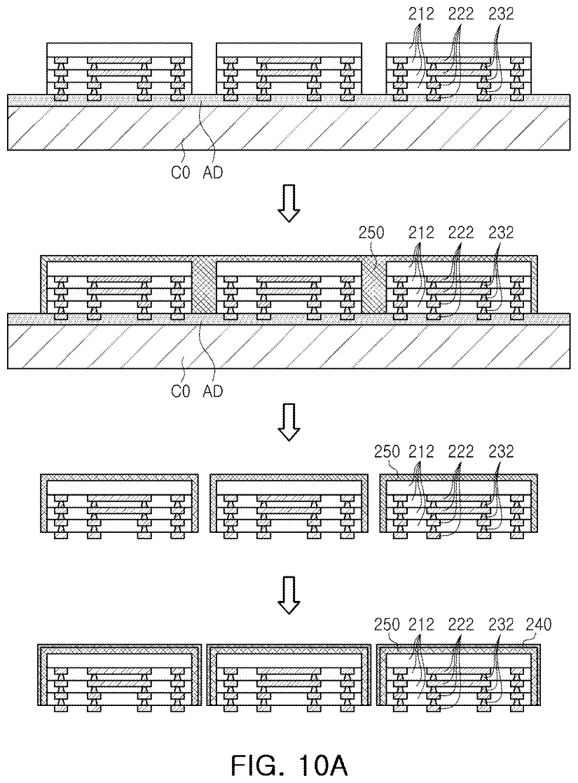

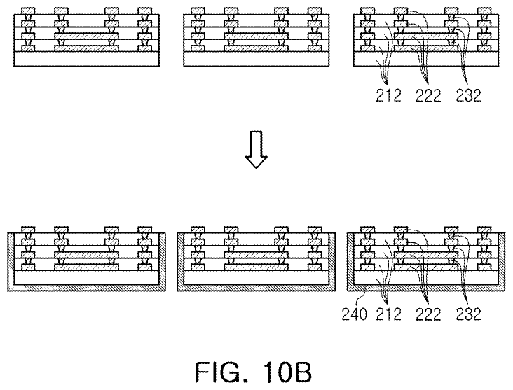

FIGS. 10A and 10B are cross-sectional views schematically illustrating method of manufacturing a connection structure according to various examples.

FIG. 10A is a cross-sectional view schematically illustrating a manufacturing method of the connection structure 200 illustrated in FIG. 9A. After forming a second wiring layer and a second via layer 232 on or within the second insulating layer 212, the second insulating layer 212 is attached to a carrier substrate CO using an adhesive film AD. In this case, the second insulating layer 212, the second wiring layer 222, and the second via layer 232 may be separately manufactured for each connection structure, or may be an operation in which a plurality of connection structures are collectively manufactured in a form of a strip substrate and then singulated through a process such as sawing. The method of manufacturing the second insulating layer 212, the second wiring layer 222, and the second via layer 232 is not limited thereto, and any method of manufacturing the connection structure 200 such as a bridge can be used without limitations.

Thereafter, an active surface of the connection structure 200 is attached to the carrier substrate CO using an adhesive film AD. In this case, the active surface of the connection structure 200 means a surface on which the connection structure 200 is mounted on a printed circuit board and connected to a semiconductor chip. The carrier substrate CO serves as a support layer, and may be used without particular limitation in the present disclosure as long as it can be used by those skilled in the art, and is used as a support substrate, so that it can be detached or removed later. Any adhesive film AD can also be used without limitation as long as may contact the connection structure 200 with the carrier substrate CO.

Thereafter, a protective layer 250 is formed to cover the second insulating layer 212 except for the active surface. The protective layer 250 may cover an outermost side surface of the second insulating layer 212, and may collectively cover each connection structure 200 as illustrated in FIG. 10A.

Thereafter, the carrier substrate CO and the adhesive film AD may be removed and each connection structure 200 may be singulated. The carrier substrate CO and the adhesive film AD may be removed using a known method such as delamination, or the like.

Thereafter, a metal layer 240 may be formed on the protective layer 250. The metal layer 240 may be deposited in a form of a thin film through sputtering, but the present disclosure is not limited thereto, and any process capable of forming the metal layer 240 on an insulating material such as the protective layer 250 can be used without limitations. By forming the metal layer 240 on the protective layer 250, an effect of EMI shielding of the connection structure 200 can be obtained.

In FIG. 10A, it is illustrated that three connection structures 200 are collectively manufactured as an example, but a larger number of connection structures 200 may be manufactured by being attached to the carrier substrate CO. Meanwhile, when the protective layer 250 is not formed, the metal layer 240 may be directly formed on the second insulating layer 212.

FIG. 10B is a cross-sectional view schematically illustrating a manufacturing method of the connection structure 200 illustrated in FIG. 9B.

FIG. 10B is a cross-sectional view schematically illustrating a manufacturing method of the connection structure 200 illustrated in FIG. 9B. After forming a second wiring layer and a second via layer 232 on or within the second insulating layer 212, a metal layer 240 may be formed on a side surface and a lower surface of the second insulating layer 212 except for the active surface. The operation of forming of the metal layer 240 may be performed using a plating process. As an example, an edge plating method may be used, and in this case, a portion of the second wiring layer 222 exposed externally of the second insulating layer 212 may be used. Meanwhile, the method of forming the metal layer 240 is not limited thereto, and any known plating method capable of forming the metal layer 240 on the side surface and lower surface of the second insulating layer 212 may be used without limitations.

As set forth above, as one effect among various effects of the present disclosure, a printed circuit board capable of performing die-to-die interconnection may be provided in a printed circuit board for mounting electronic components and semiconductor chip.

As another effect among various effects of the present disclosure, a printed circuit board capable of protecting a connection structure from factors inside and outside the board during die-to-die interconnection may be provided.

As another effect among various effects of the present disclosure, a printed circuit board capable of improving reliability may be provided.

In the example embodiment, the meaning on a cross-section may mean a cross-sectional shape when the object is vertically cut, or a cross-sectional shape when the object is viewed from a side-view. Also, the meaning on a plane may be a shape when the object is horizontally cut, or a planar shape when the object is viewed from a top-view or a bottom-view.

In the example embodiment, the upper side, the upper side, the upper surface, or the like, are used to refer to the direction toward the mounting surface on which the electronic component is mounted based on the cross-section of the drawing for convenience, and the lower side, the lower side, the lower surface, or the like, are used as the opposite directions. However, the direction is defined as above for ease of description, and the scope of the claims is not limited to any particular example by the descriptions of the directions.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to a person skilled in the art that modifications and variations could be made without departing from the scope of the present disclosure as defined by the appended claims.

What is claimed is:

1. A printed circuit board, comprising:
a substrate portion including a first insulating layer, a first wiring layer disposed on or within the first insulating layer, and a cavity penetrating through at least a portion of the first insulating layer;
a connection structure disposed within the cavity of the substrate portion, and including a second insulating layer, a second wiring layer disposed on or within the second insulating layer, and a metal layer disposed on a lower surface and a side surface of the second insulating layer,
wherein the metal layer is disposed on an outermost side of the connection structure.

2. The printed circuit board of claim 1, wherein the connection structure further comprises a protective layer disposed between the metal layer and the second insulating layer.

3. The printed circuit board of claim 2, wherein a thickness of the metal layer is less than a thickness of the protective layer.

4. The printed circuit board of claim 1, wherein the metal layer comprises at least one of copper (Cu), aluminum (Al), nickel (Ni), silver (Ag), tin (Sn), gold (Au), nickel (Ni), lead (Pb), titanium (Ti), molybdenum (Mo), and stainless metal (SUS).

5. The printed circuit board of claim 1, wherein the metal layer is in contact with a lower surface and a side surface of the second insulating layer.

6. The printed circuit board of claim 1, wherein the metal layer is disposed to be spaced apart from a bottom surface and a wall surface of the cavity.

7. The printed circuit board of claim 6, wherein the substrate portion further comprises
an adhesive layer disposed between the bottom surface of the cavity and the connection structure.

8. The printed circuit board of claim 6, wherein the substrate portion further comprises
a third insulating layer disposed on the first insulating layer and disposed in the cavity to cover the connection structure, and a third wiring layer disposed on the first insulating layer.

9. The printed circuit board of claim 8, wherein the substrate portion further comprises
a solder resist layer disposed on the third insulating layer and including an opening.

10. The printed circuit board of claim 1, wherein an upper surface of the second insulating layer and an upper surface of the metal layer are substantially coplanar.

11. The printed circuit board of claim 10, wherein the connection structure further comprises a protective layer disposed between the metal layer and the second insulating layer,
wherein an upper surface of the protective layer and an upper surface of the metal layer are substantially coplanar.

12. The printed circuit board of claim 1, wherein wiring density of the second wiring layer is greater than wiring density of the first wiring layer.

13. The printed circuit board of claim 12, wherein a thickness of any one of the second insulating layers is less than a thickness of any one of the first insulating layers.

14. The printed circuit board of claim 1, wherein the first insulating layer and the second insulating layer comprise an organic material, respectively.

15. The printed circuit board of claim 1, further comprising:
a first semiconductor chip disposed on a portion of the substrate portion and a portion of the connection structure, and connected to a portion of the substrate portion and a portion of the connection structure; and
a second semiconductor chip disposed on another portion of the substrate portion and another portion of the connection structure, and connected to another portion of the substrate portion and another portion of the connection structure and connected to the first semiconductor chip through the connection structure.

16. The printed circuit board of claim 1, wherein the connection structure includes first and second surfaces opposing each other in which the second surface faces a bottom surface of the cavity, and third and fourth surfaces opposing each other, and
the metal layer provides only the second to fourth surfaces among the first to fourth surfaces of the connection structure.

17. A printed circuit board, comprising:
a substrate portion including a first insulating layer, a first wiring layer disposed on or within the first insulating layer, and a cavity penetrating through at least a portion of the first insulating layer; and
a connection structure disposed within the cavity of the substrate portion, and including a second insulating layer, a second wiring layer disposed on or within the second insulating layer, a protective layer covering a lower surface and a side surface of the second insulating layer, and a metal layer disposed on the protective layer.

18. The printed circuit board of claim 17, wherein the protective layer and the metal layer each include a portion substantially coplanar with a portion of the second insulating layer.

19. The printed circuit board of claim 17, wherein a thickness of the metal layer is less than a thickness of the protective layer.

20. The printed circuit board of claim 17, wherein the connection structure includes first and second surfaces opposing each other in which the second surface faces a bottom surface of the cavity, and third and fourth surfaces opposing each other, and
the metal layer provides only the second to fourth surfaces among the first to fourth surfaces of the connection structure.
